(19) United States
(12) Patent Application Publication
(10) Pub. No.: US 2017/0155044 A1
(43) Pub. Date: Jun. 1, 2017

(54) NONVOLATILE RESISTANCE RANDOM ACCESS MEMORY DEVICE WITH LOW AND RELIABLE OPERATING VOLTAGE AND LONG-TERM STABILITY AND FABRICATION METHOD THEREOF

(71) Applicant: KOREA INSTITUTE OF SCIENCE AND TECHNOLOGY, Seoul (KR)

(72) Inventors: Jong Hyuk PARK, Seoul (KR); Sang-Soo LEE, Seoul (KR); Heesuk KIM, Seoul (KR); Jeong Gon SON, Seoul (KR); Wan Ki BAE, Seoul (KR); Keun-Young SHIN, (US); Young Jin KIM, (US)

(21) Appl. No.: 15/229,449

(22) Filed: Aug. 5, 2016

(30) Foreign Application Priority Data
Nov. 27, 2015 (KR) 10-2015-0167711

(51) Int. Cl. H01L 45/00

(52) U.S. Cl. CPC H01L 45/16; H01L 45/1616; H01L 45/1625; H01L 45/1233

(57) ABSTRACT

Disclosed are nonvolatile resistance random access memory device and a fabrication method thereof. The nonvolatile resistance random access memory device includes a lower electrode, an insulator film formed on a surface of the lower electrode, and an upper electrode formed over the insulator film, the lower electrode includes a base, and a thin metal layer formed on a surface of the base, and the lower electrode has a 3D structural pattern in which a plurality of protruding structures is repeatedly arranged at a constant interval. The 3D metal structures have a shape selected from among a pyramid (quadrangular pyramid), a trapezoidal pyramid (pyramid with a flat top), a pillar, and a prism. Uniform conductive filaments are formed via the space between the 3D metal structures, whereby the nonvolatile resistance random access memory device is capable of being driven at a low operating voltage and has long-term stability.

### CROSS-REFERENCE TO RELATED APPLICATIONS

This application claims priority under 35 U.S.C. §119 to Korean Patent Application No. 10-2015-0167711 filed on Nov. 27, 2015 in the Korean Intellectual Property Office, the disclosure of which is incorporated herein by reference in its entirety.

### BACKGROUND OF THE INVENTION

Field of the Invention

The present invention relates to a nonvolatile resistance random access memory device and a fabrication method thereof, and more particularly, to a nonvolatile resistance random access memory device, which may be driven at a low operating voltage owing to uniform conductive filaments, and may have a 3-dimensional (3D) structural pattern including a thin metal layer so as to exhibit long-term stability, and a fabrication method thereof.

Description of the Related Art

As the advent of the information and communication age has arrived, the requirement to improve the performance of semiconductor devices and systems, which have the ability to rapidly process a greater number of pieces of information, is becoming more important. To this end, memory devices, which are core elements thereof, are essentially required to exhibit ultrahigh speed, ultrahigh density integration, and ultralow power consumption.

Among various next-generation memories, a nonvolatile resistance random access memory (ReRAM) device is a kind of nonvolatile memory that has a simplified Metal-Insulator-Metal (MIM) thin film structure and utilizes rapid variation in the resistance of a thin film depending on the specific voltage that is applied to the thin film. The nonvolatile ReRAM device has advantages such as, for example, no deterioration in infinite recording and playback, the ability to operate at high temperatures, and the safety of data. In addition, when an input pulse is applied thereto, the nonvolatile ReRAM device is operable at high speeds within the range from 10 ns to 20 ns with variation in resistance up to 1000 times or more, and enables high integration owing to the thin film structure thereof, thus minimizing the consumption of energy.

The nonvolatile ReRAM device preferentially requires an electro-forming operation in order to exhibit the desired behavior. When a prescribed voltage is applied to upper and lower electrodes, conductive filaments are formed in an insulator film. As current flows through the conductive filaments, the nonvolatile ReRAM device exhibits switching in which electrical properties vary from a high resistance state to a low resistance state. Through the formation or extinction of conduction paths including the filaments described above, the insulator film attains two resistance states, which are distinguishable from each other. That is, variation to the low resistance state is referred to as a set operation, and conversely, variation to the high resistance state is referred to as a reset operation.

However, in the case of a conventional nonvolatile ReRAM device, conductive filaments are irregularly formed, and due to this, the differently formed conductive filaments cause a high operating voltage and nonuniform set/reset current distribution in repeated resistive switching operations, thus resulting in, for example, low long-term stability.

### PRIOR ART DOCUMENT

### Patent Document

1. Korean Patent Laid Open Publication No. 10-2014-0134428

2. Korean Patent Laid Open Publication No. 10-2014-0046613

3. Korean Patent Laid Open Publication No. 10-2011-0073648

### SUMMARY OF THE INVENTION

Therefore, the present invention has been made in view of the above problems, and it is an object of the present invention to provide a nonvolatile resistance random access memory device, which is configured so as to be driven at a low operating voltage and to achieve the uniform distribution of set/reset current, and a fabrication method thereof.

In accordance with an aspect of the present invention, to accomplish the above and other objects, there is provided a nonvolatile resistance random access memory device including a lower electrode, an insulator film formed on a surface of the lower electrode, and an upper electrode formed over the insulator film, wherein the lower electrode includes a base, and a thin metal layer formed on a surface of the base, and wherein the lower electrode has a 3D structural pattern in which a plurality of protruding structures is repeatedly arranged at a constant interval.

The nonvolatile resistance random access memory device in accordance with the present invention enables the formation of uniform conductive filaments through spaces between the protruding structures.

According to the present invention, the protruding structures of the lower electrode may have a shape selected from among a pyramid, a trapezoidal pyramid (pyramid with a flat top), a pillar, and a prism, may have a height within a range from 100 nm to 100 and a width (or diameter) within a range from 100 nm to 100 and an interval (distance) between one structure and an adjacent structure may be within a range from 100 nm to 100 nm.

According to the present invention, the structures of the lower electrode may have a shape of a pyramid, and a tip of the pyramid may include a curved surface and may have a radius of curvature within a range from 10 nm to 100 nm.

According to the present invention, the base may be formed of a polymer resin or metal, the polymer resin may be any one selected from among acryl resin, urethane resin, epoxy resin, polyester resin, phenol resin, polyvinyl chloride, amino, and polyacetal, and the metal may be any one selected from among silver (Ag), copper (Cu), nickel (Ni), chrome (Cr), platinum (Pt), gold (Au), lead (Pb), ruthenium (Ru), and palladium (Pd).

According to the present invention, the thin metal layer of the lower electrode may have a thickness within a range from 10 nm to 1000 nm.

According to the present invention, the insulator film may be formed by depositing one kind of metal oxide selected from among NiO, SiO₂, TiO₂, ZnO, HfO₂, Nb₂O₅, MgO, Al₂O₃, Ta₂O₅, CuO, ZrO₂, and Fe₂O₃, on a surface of the lower electrode, and the insulator film may have a thickness within a range from 10 nm to 1000 nm.

According to the present invention, the upper electrode may have a thickness within a range from 10 nm to 1000 nm.

According to the present invention, the nonvolatile resistance random access memory device may have a set operating voltage within a range from 0.3 V to 1.0 V, a reset operating voltage within a range from 0.01 V to 0.3 V, and a resistance ratio within a range from 10⁴ to 10⁶.

In accordance with another aspect of the present invention, there is provided a method of fabricating a nonvolatile resistance random access memory device, the method including forming a mask on a substrate, forming a mask pattern on the mask, etching the substrate by performing a dry etching process on the substrate, on which the mask pattern has been formed, fabricating a silicon template by performing a wet etching process on the dry-etched substrate, fabricating a lower electrode including a 3D structural pattern in which protruding structures are repeatedly arranged at a constant interval by performing operations of forming a thin metal layer on the silicon template by depositing a first metal, and of forming a base by performing a template stripping process or an electroplating process, which includes a polymer curing process, on the silicon template on which the thin metal layer has been formed, fabricating an insulator film by depositing a metal oxide on a surface of the lower electrode, and fabricating an upper electrode by depositing a second metal over the insulator film.

### BRIEF DESCRIPTION OF THE DRAWINGS

The above and other objects, features and other advantages of the present invention will be more clearly understood from the following detailed description taken in conjunction with the accompanying drawings, in which:

FIG. 1A is a diagram illustrating a nonvolatile resistance random access memory (ReRAM) device fabricated in accordance with one embodiment of the present invention, and FIG. 1B is an image of the nonvolatile resistance random access memory device fabricated in accordance with one embodiment of the present invention, which is captured by a scanning electron microscope (Ag: a lower electrode based on a 3-dimensional (3D) metal (Ag) pyramid pattern, Al₂O₃: an insulator film, and Pt: an upper electrode);

FIG. 2 is a real image of the nonvolatile resistance random access memory device fabricated in accordance with one embodiment of the present invention;

FIG. 3 is a view illustrating the magnitude of an electric field, which is created around the tip (apex) of a 3D metal pyramid fabricated in accordance with one embodiment of the present invention;

FIG. 4 is a diagram illustrating a method of fabricating a lower electrode, which has a 3D metal structural pattern, in a nonvolatile resistance random access memory (ReRAM) device in accordance with one embodiment of the present invention;

FIG. 5 is a diagram illustrating a method of fabricating a lower electrode, which has a 3D metal structural pattern, in a nonvolatile resistance random access memory (ReRAM) device in accordance with another embodiment of the present invention;

FIGS. 6A to 6C are images of a mask pattern fabricated in accordance with one embodiment of the present invention, which are captured by a scanning electron microscope;

FIGS. 7A and 7B are images of a substrate, on which a dry etching process has been performed, in accordance with one embodiment of the present invention, which are captured by a scanning electron microscope;

FIGS. 8A to 8C are images of a 3D metal pyramid pattern fabricated in accordance with one embodiment of the present invention, which are captured by a scanning electron microscope;

FIGS. 9A to 9C are enlarged images of various 3D metal pyramid patterns fabricated in accordance with one embodiment of the present invention, which are captured by a scanning electron microscope (FIG. 9A illustrating an Ag pyramid, FIG. 9B illustrating a Cu pyramid, and FIG. 9C illustrating a Ni pyramid);

FIGS. 10A to 10C are images of 3D metal structural patterns having various configurations fabricated in accordance with one embodiment of the present invention, which are captured by a scanning electron microscope (FIG. 10A illustrating a pyramid with the flat top, FIG. 10B illustrating a prism, and FIG. 10C illustrating a pillar); and

FIGS. 11A and 11B are graphs illustrating the measured results of the performance of the nonvolatile resistance random access memory device fabricated in accordance with one embodiment of the present invention (FIG. 11A illustrating a comparative example and FIG. 11B illustrating an example);

FIG. 12 is a diagram illustrating a method of fabricating a lower electrode, which has an electroplating methods on the silicon template by depositing a first metal fabricated in accordance with one embodiment of the present invention.

### DETAILED DESCRIPTION OF THE INVENTION

Hereinafter, the present invention will be described in more detail with reference to the accompanying drawings.

The present invention provides a nonvolatile resistance random access memory (ReRAM) device, which is reliably drivable at a low operating voltage owing to the uniformity of conductive filaments and has long-term stability.

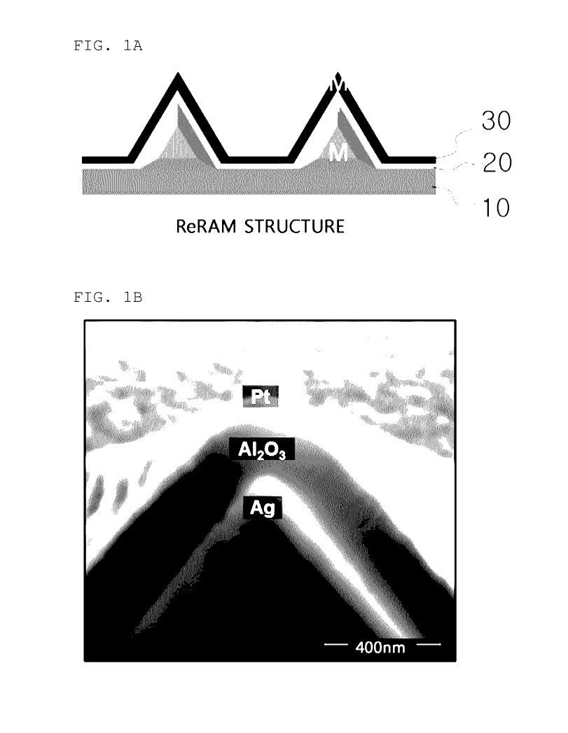

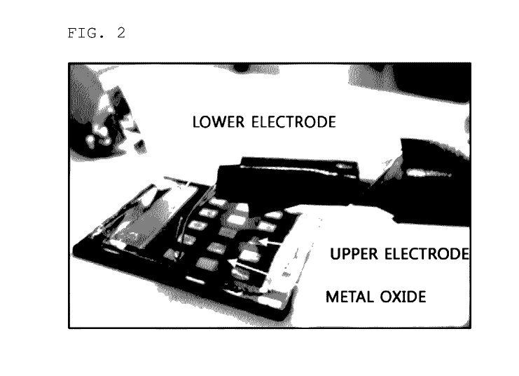

Referring to FIGS. 1A and 2, the nonvolatile resistance random access memory device in accordance with the present invention includes a lower electrode 10, an insulator film 20 formed on the surface of the lower electrode 10, and an upper electrode 30 formed on the insulator film 20. The lower electrode 10 is comprised of a base, and a thin metal layer formed on the surface of the base. The lower electrode 10 has a 3-dimensional (3D) structural pattern in which a plurality of protruding structures is repeatedly arranged at a constant interval.

According to the present invention, uniform conductive filaments may be formed thanks to the spaces between the protruding structures.

The 3D structural pattern has a feature such that it enables the conductive filaments to be uniformly formed inside the insulator film 20 despite repeated resistance switching operations, whereby the nonvolatile resistance random access memory device is reliably driven even at a low operating voltage and achieves improvement in switching reproducibility and uniformity.

According to the present invention, the protruding structures of the lower electrode 10 may have any shape selected from among a pyramid (i.e. a quadrangular pyramid), a prism, a pillar, and a trapezoidal pyramid (i.e. a pyramid with the flat top), without being limited thereto. The protruding structures may have the shape of a polypyramid or a polypyramid with the flat top.

The trapezoidal pyramid is a pyramid having a trapezoidal side surface and a flat upper surface. The polypyramid is a pyramid having a polygonal lower surface and a triangular side surface. Here, the polygon may be selected from among a triangle, square, pentagon, hexagon, octagon, and hexadecagon, without being limited thereto, and the pyramid may have a square lower surface.

According to the present invention, the shape of the structures may be that of a pyramid or trapezoidal pyramid, and more particularly, a pyramid. In particular, the shape of the structures may be that of a pyramid having a curved tip, the radius of curvature of which is within the range from 10 nm to 100 nm. When the tip of the pyramid is a curved surface having the radius of curvature within the range from 10 nm to 100 nm, in particular, it was found that the distribution current is uniform compared to other structure shapes and that driving at a low set/reset operating voltage and excellent reproducibility are accomplished. On the other hand, when the tip of the pyramid is a curved surface, the radius of curvature of which exceeds 100 nm, or when the tip of the pyramid is a flat surface, it was found that memory performance is deteriorated compared to the case where the tip of the pyramid is the curved shape, the radius of curvature of which is within the range from 10 nm to 100 nm. In addition, when the tip of the pyramid has an inclined surface or an uneven structure (a convex and concave structure), it was found that the amplification of an electric field is deteriorated due to the problem whereby the electric field is not uniformly formed, and that memory performance is deteriorated.

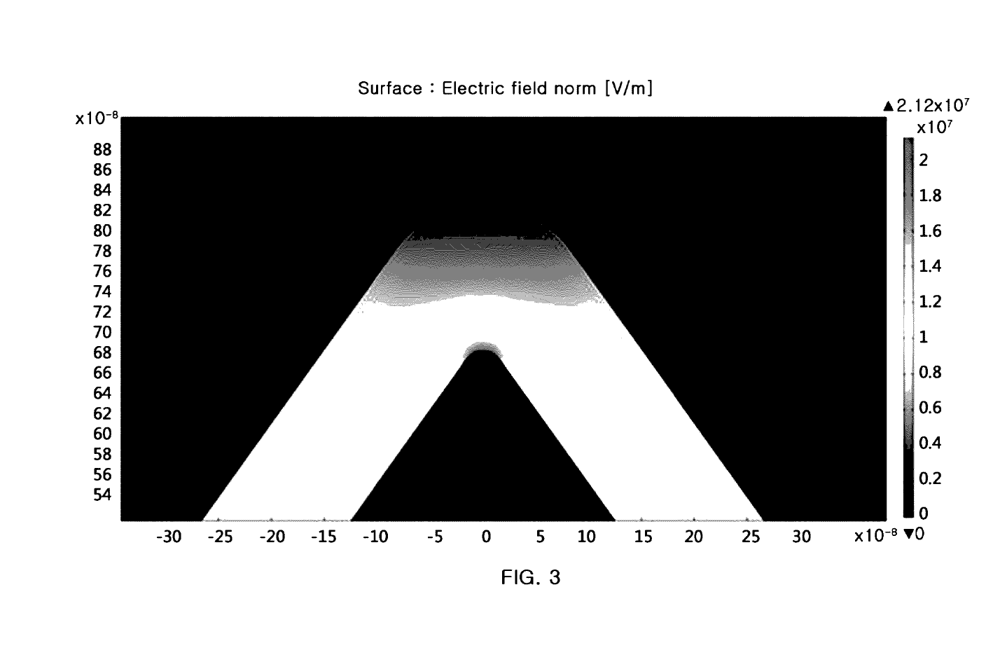

Specifically, when the lower electrode 10 in accordance with the present invention is applied to a memory, conductive filaments inside the memory are formed around the tip of the respective 3D structures. Referring to FIG. 3, it can be appreciated that the largest electric field is formed near the tip of the pyramid. The lower electrode 10 having the 3D pyramids maximizes the amplification of the electric field and causes the filaments to be formed even at a relatively low voltage. Accordingly, the operating voltage of the memory is reduced, and the filaments are formed around the tip of the respective 3D structures, which results in improved reliability. The electric field may vary based on variables such as, for example, the shape, size, and radius of curvature of the 3D structures, and the memory performance may also vary based on the variables.

According to the present invention, the protruding structures have a height within the range from 100 nm to 100 μm, and a width or diameter within the range from 100 nm to 100 and the interval (distance) between one structure and an adjacent structure may be within the range from 100 nm to 100 m.

A protruding structure, the height, width and diameter of which are below 100 nm respectively, is not easily fabricated. In addition, when height, width and diameter of the structure exceeds 100 the degree of memory integration is low, thus causing deterioration in memory performance

The protruding structure in accordance with the present invention may include a base and a thin metal layer formed on the surface of the base.

In addition, when the distance between one structure and an adjacent structure is less than 100 nm or exceeds 100 the degree of integration is reduced, which causes deterioration in memory performance.

According to the present invention, the base may be formed of a polymer resin or metal. The polymer resin may be any one selected from among acryl resin, urethane resin, epoxy resin, polyester resin, phenol resin, polyvinyl chloride, amino, and polyacetal, or a blend of two or more of them, without being limited thereto. In addition, the metal may be any one selected from among silver (Ag), copper (Cu), nickel (Ni), chrome (Cr), platinum (Pt), gold (Au), lead (Pb), ruthenium (Ru), and palladium (Pd).

According to the present invention, the thin metal layer formed on the surface of the base may be formed by depositing one selected from among platinum, nickel, tungsten, gold, silver, copper, titanium, aluminum, cobalt, tin, palladium, zinc, manganese, and iron, and the thickness of the thin metal layer may be within the range from 10 nm to 1000 nm.

When the thickness of the thin metal layer is below 10 nm, use as the lower electrode is difficult because of deterioration in memory performance. When the thickness of the thin metal layer exceeds 1000 nm, it is not easy to form the lower electrode using a template stripping process.

Next, the insulator film 20 of the nonvolatile resistance random access memory device in accordance with the present invention may be formed by depositing one kind of metal oxide, selected from among NiO, SiO₂, TiO₂, ZnO, HfO₂, Nb₂O₅, MgO, Al₂O₃, Ta₂O₅, CuO, ZrO₂, and Fe₂O₃, on the surface of the lower electrode 10, but the metal oxide is not limited thereto.

According to the present invention, the thickness of the insulator film 20 may be within the range from 10 nm to 1000 nm. When the thickness of the insulator film 20 is below 10 nm, the formation of the insulator film may be difficult. When the thickness of the insulator film 20 exceeds 1000 nm, the excessively thick insulator film makes it difficult for the conductive filaments to be formed therein based on an external voltage.

Meanwhile, in the nonvolatile resistance random access memory device in accordance with the present invention, the upper electrode 30 may be formed of one selected from among platinum, nickel, tungsten, gold, silver, copper, titanium, aluminum, cobalt, tin, palladium, zinc, manganese, and iron, and the thickness of the upper electrode 30 may be at least 10 nm or more, and more particularly, may be within the range from 10 nm to 1000 nm. When the thickness of the upper electrode 30 deviates from the range described above, the formation of the electrode is difficult.

The nonvolatile resistance random access memory device in accordance with the present invention may have a feature such that a set operating voltage thereof is within the range from 0.3 V to 1.0 V, a reset operating voltage thereof is within the range from 0.01 V to 0.3 V, and a resistance ratio thereof is within the range from 10⁴ to 10⁶, owing to the structural features described above.

Next, the method of fabricating the nonvolatile resistance random access memory device in accordance with the present invention will be described.

The nonvolatile resistance random access memory device in accordance with the present invention may be fabricated by performing the following operations:
(a) forming a mask on a substrate;
(b) forming a mask pattern on the mask;
(c) etching the substrate by performing a dry etching process on the substrate, on which the mask pattern has been formed;
(d) fabricating a silicon template by performing a wet etching process on the dry-etched substrate;
(e) fabricating a lower electrode including a 3D structural pattern in which protruding structures are repeatedly arranged at a constant interval by performing the operations of forming a thin metal layer on the silicon template by depositing a first metal, and of forming a base by performing a template stripping process or an electroplating process, which includes a polymer curing process, on the silicon template on which the thin metal layer has been formed;
(f) fabricating an insulator film by depositing a metal oxide on the surface of the lower electrode; and
(g) fabricating an upper electrode by depositing a second metal over the insulator film.

According to the present invention, the substrate may be a p-type or n-type silicon substrate coated with silicon dioxide (SiO₂) or silicon nitride (SiN), and the silicon dioxide or silicon nitride coating layer may have a thickness of 100 nm or more, and more particularly, a thickness within the range from 100 nm to 1000 nm, in order to fabricate the mask pattern.

Subsequently, a mask is formed on the p-type or n-type silicon substrate (hereinafter referred to as “substrate”) coated with silicon dioxide (SiO₂) or silicon nitride (SiN). The method of forming the mask is not particularly limited, and the coating material may be applied to the substrate via a method such as, for example, spin coating, screen printing, inkjet printing, or gravure.

Subsequently, a mask pattern is formed on the mask. The mask pattern may be formed using a common lithography process, without being particularly limited thereto. For example, the lithography process may be any one selected from among nanosphere lithography, focused ion beam (FIB) milling, optical lithography (photolithography), electron beam lithography, and interference lithography.

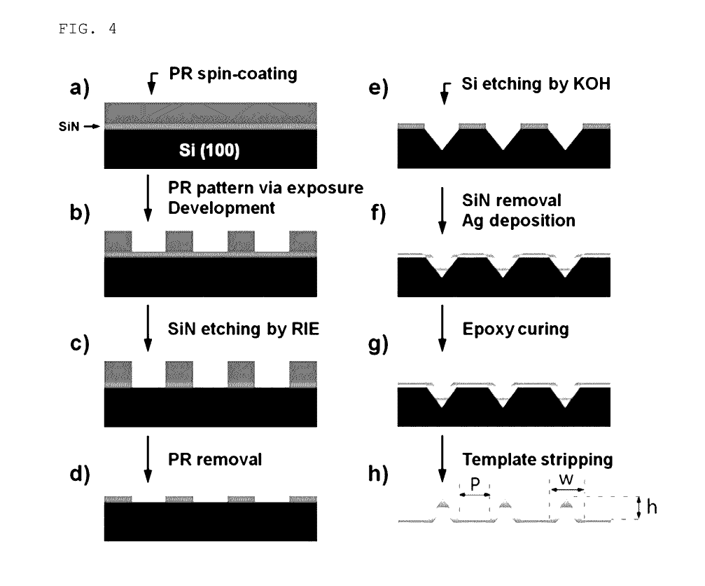

FIG. 4 illustrates a method of forming the pattern on the substrate using optical lithography (FIGS. 4A and 4B), and FIG. 5 illustrates a method of forming the pattern on the substrate using nanosphere lithography (FIGS. 5A to 5D).

The mask pattern, formed by the lithography process, may be a dot pattern in which circular structures are repeatedly formed, or a striped pattern in which bar-shaped structures are repeatedly formed, without being limited thereto. According to the present invention, the circular or bar-shaped structures of the mask pattern may have a depth within the range from 100 nm to 100 μm, and a width (or diameter) of at least 100 nm or more, and more particularly, within the range from 100 nm to 100 μm, and the distance between one structure and an adjacent structure may be at least 100 nm or more, and more particularly, within the range from 100 nm to 100 μm.

When the size of the structures and the distance between one structure and a next structure are below the ranges described above, resolution may be deteriorated when a photoresist pattern is formed. When the size of the structures and the distance between the structures exceed the ranges described above, the performance of the fabricated nonvolatile resistance random access memory device may be deteriorated.

Subsequently, the substrate, on which the mask pattern has been formed, may be subjected to a dry etching process. The dry etching process may be selected from among reactive ion etching (RIE) and inductively coupled plasma etching (ICP).

The depth of the substrate, etched via the dry etching process, may be at least 100 nm. The depth of the substrate may be set to a value suitable for the sufficient removal of the silicon dioxide (SiO₂) or silicon nitride (SiN) layer coated over the substrate.

According to the present invention, when the silicon oxide or silicon nitride layer within the mask pattern area is not completely removed after the dry etching process, a subsequent operation for the wet etching of the silicon substrate may not be performed.

According to the present invention, the substrate, etched via the dry etching process, may be washed using a wash solution, thus enabling the washing of the mask. The wash solution may be, for example, acetone.

Subsequently, the wet etching process may be performed at 60° C. to 70° C. for a time ranging from 1 minute to 10 minutes using a potassium hydroxide solution having a molar concentration within the range from 4.5 M to 6.5 M. When the molar concentration of the potassium hydroxide solution is below 4.5 M, it is difficult to perform a silicon etching process. When the molar concentration of the potassium hydroxide solution exceeds 6.5 M, defects may be generated on the surface of the silicon substrate. In addition, when the reaction temperature of the wet etching process is below 60° C., it is difficult to perform a silicon etching process. When the reaction temperature of the wet etching process exceeds 70° C., defects may be generated on the surface of the silicon substrate. In addition, when the time taken to perform the wet etching process is below 1 minute, it is difficult to perform a silicon etching process. When the time taken to perform the wet etching process exceeds 10 minutes, this is not necessary because it is etching no longer.

According to the present invention, the silicon substrate, etched in the wet etching process, may be processed using hydrogen fluoride (HF) in order to remove silicon dioxide or silicon nitride.

Through the processes described above, a silicon template is completed.

Prior to using the silicon template, the surface of the silicon template may be washed using a piranha solution, and a chemical oxide film may be formed thereon.

Subsequently, a lower electrode is fabricated using the silicon template. First, a first metal is deposited on the silicon template. The deposited first metal forms a thin metal layer of the lower electrode.

According to the present invention, the first metal may be one selected from among platinum, nickel, tungsten, gold, silver, copper, titanium, aluminum, cobalt, tin, palladium, zinc, manganese, and iron.

The deposition may be one of sputtering, atomic layer deposition (ALD), thermal evaporation, pulsed laser deposition (PLD), electron beam evaporation, physical vapor deposition (PVD), and chemical vapor deposition (CVD), without being limited thereto.

According to the present invention, the metal may be deposited to a thickness within the range from 10 nm to 1000 nm. When the thickness of the deposited metal deviates from the above range, the formation of the lower electrode using a template stripping process is difficult.

Next, a base is formed over the thin metal layer. The base may be formed of a polymer resin layer, which is formed via a template stripping process including a polymer curing process, or a metal layer, which is formed via an electroplating process.

The polymer resin layer may be any one selected from among acryl resin, urethane resin, epoxy resin, polyester resin, phenol resin, polyvinyl chloride, amino, and polyacetal, or a blend of two or more of them. The metal layer may be formed of any one metal selected from among silver (Ag), copper (Cu), nickel (Ni), chrome (Cr), platinum (Pt), gold (Au), lead (Pb), ruthenium (Ru), and palladium (Pd).

According to the present invention, the thickness of the metal layer, deposited by the electroplating process, may be at least 20 m or more, and more particularly, within the range from 20 m to 1 mm. When the thickness of the metal layer is below 20 μm, stripping is not easy. Deposition to thicknesses above 1 mm has no effect on the performance of the memory device, and thus is economically inefficient.

According to the present invention, the shape of the protruding structures may be selected from among a pyramid, a trapezoidal pyramid (a pyramid with the flat top, a pillar, and a prism. The shape and size of the structures may be determined by adjusting the concentration of the potassium hydroxide solution and the duration of the wet etching process.

The lower electrode, fabricated by the method described above, is comprised of the base and the thin metal layer formed on the surface of the base, and has a 3D structural pattern in which protruding structures are repeatedly arranged at a constant interval.

The 3D structural pattern and the shape and features of the structures are as defined above, and the structures may be pyramids, the tip of each of which is formed with a curved surface having a radius of curvature within the range from 10 nm to 100 nm, in terms of excellent memory performance.

Next, an insulator film is formed by depositing a metal oxide on the surface of the lower electrode, more specifically, the thin metal layer of the lower electrode.

The metal oxide may be any one selected from among NiO, SiO₂, TiO₂, ZnO, HfO₂, Nb₂O₅, MgO, Al₂O₃, Ta₂O₅, CuO, ZrO₂, and Fe₂O₃.

The deposition of the metal oxide in accordance with the present invention may be performed using one process selected from among sputtering, atomic layer deposition, thermal evaporation, pulsed laser deposition, electron beam evaporation, physical vapor deposition, and chemical vapor deposition.

According to the present invention, the thickness of the metal oxide insulator film may be within the range from 10 nm to 1000 nm. When the thickness of the metal oxide is below 10 nm, the formation of the insulator film is difficult. When the thickness of the metal oxide exceeds 1000 nm, the formation of conductive filaments inside the insulator film based on an external voltage is difficult.

Subsequently, an upper electrode is fabricated by depositing a second metal on the insulator film. The second metal may be one selected from among platinum, nickel, tungsten, gold, silver, copper, titanium, aluminum, cobalt, tin, palladium, zinc, manganese, and iron, and the deposition may be performed via any one selected from among sputtering, atomic layer deposition, thermal evaporation, pulsed laser deposition, electron beam evaporation, physical vapor deposition, and chemical vapor deposition, without being limited thereto. The thickness of the metal, deposited as the upper electrode, may be at least 10 nm or more, and more particularly, may be within the range from 10 nm to 1000 nm.

Hereinafter, the present invention will be described in more detail below with reference to examples. However, the examples are provided only to describe the present invention in more detail, and it will be apparent to those skilled in the art that the scope of the present invention is not limited by the examples.

### EXAMPLE 1

A p-type silicon substrate, which was coated with a 100 nm silicon nitride layer, was placed in a glass tank containing isopropyl alcohol(IPA), and the substrate was washed using an ultrasonic process. The washed substrate was again washed using isopropyl alcohol and blown with nitrogen. The washed substrate was placed in a glass tank containing methanol, and was again washed using an ultrasonic process, and thereafter was washed using methanol and blown with nitrogen. The washed substrate was placed in a glass tank containing acetone, and was again washed using an ultrasonic process. Thereafter, the substrate was completely washed using acetone and blown with nitrogen.

The washed substrate was subjected to a pre-annealing process at 120° C. for 60 seconds using a hot plate. The pre-annealed substrate was coated with an embossed photoresist (GXR 601) using spin coating equipment. Specifically, the coating was formed by applying a photoresist solution over the substrate, and performing spin coating at 500 rpm for 5 seconds and then again at 4000 rpm for 30 seconds so as to form a photoresist having a thickness of approximately 1 m.

The substrate having the photoresist formed thereon was subjected to a soft baking process at 100° C. for 90 seconds using a hot plate.

The substrate, having undergone the soft baking process, was subjected to an exposure process using mask aligner equipment. The exposure process was performed using a chrome photomask having a circular pattern and a mercury lamp, which had an output voltage of 20 mW and emits monochromatic light within the wavelength range of 365 nm. The exposure process was performed for 3 seconds using a low vacuum contact method. The substrate having the exposed photoresist was subjected to a developing process for 20 seconds using an AZ 300 MIF developing solution. The substrate having the developed photoresist was washed using distilled water and nitrogen gas, and was subjected to a hard baking process at 120° C. for 60 seconds using a hot plate.

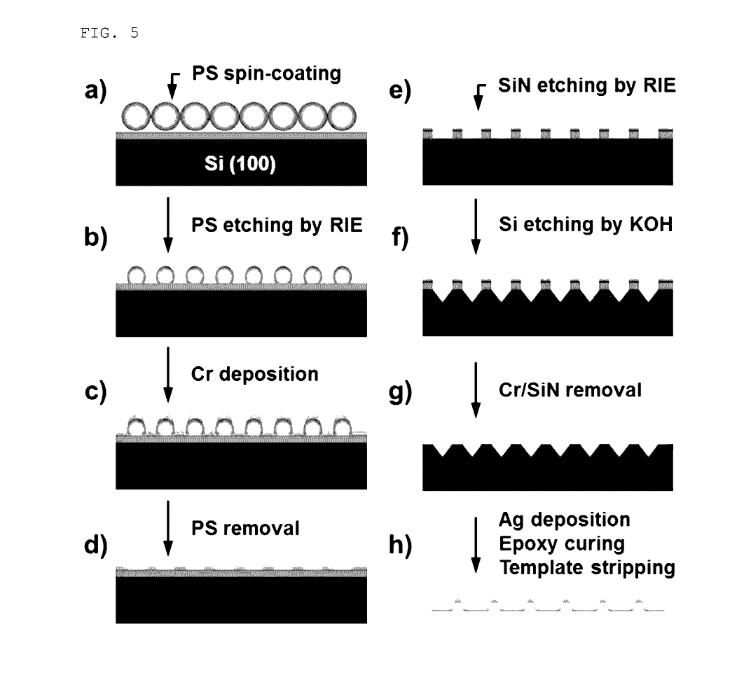

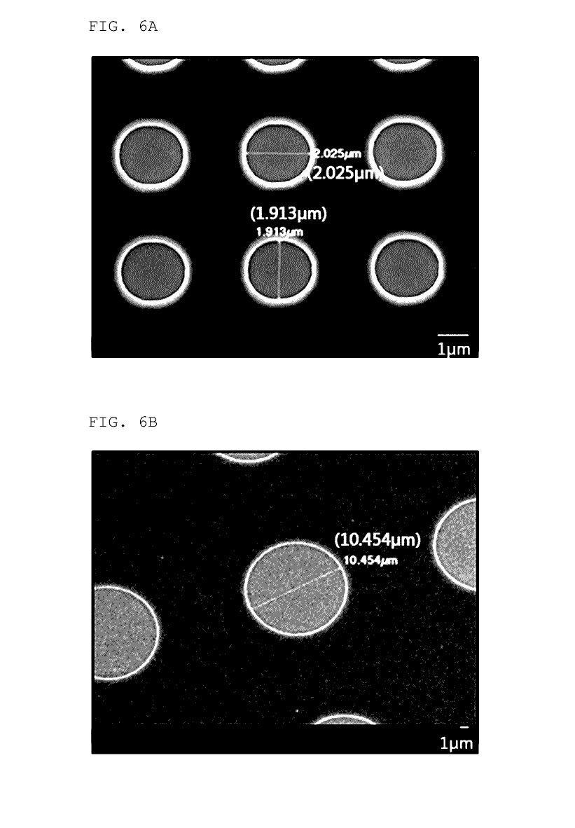

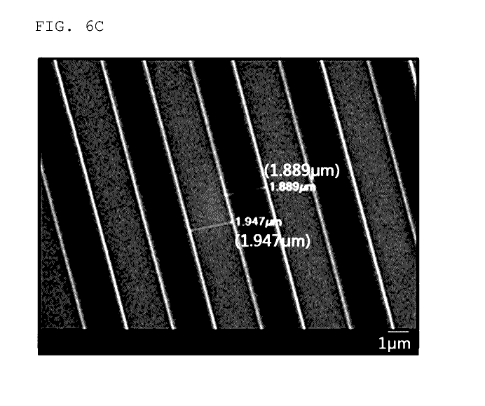

As a result of analysis of the photoresist substrate, having undergone the exposure and developing processes, using a scanning electron microscope, as illustrated in FIG. 6A, a photoresist pattern in which circular structures, having a diameter of approximately 2 μm and a distance therebetween of approximately 2 μm, were repeatedly formed, was confirmed.

### EXAMPLE 2

A photoresist pattern, in which circular structures, having a diameter of approximately 10 m and a distance therebetween of approximately 10 μm, were repeatedly formed as illustrated in FIG. 6B, was fabricated using the same method as that in Example 1.

### EXAMPLE 3

A striped photoresist pattern, in which bar-shaped structures were repeatedly formed as illustrated in FIG. 6C, was fabricated using the same method as that in Example 1 except that the exposure and developing processes were performed using a chrome photomask having a striped pattern. Based on electromicroscopic analysis results, the striped photoresist pattern, in which the width of the bar-shaped structures was approximately 2 μm and the distance between the bar-shaped structures was approximately 2 μm, was fabricated.

### EXAMPLE 4

The substrate fabricated in Example 1, on which the dotted photoresist pattern, in which the diameter of the circular structures was approximately 2 μm and the distance between the circular structures was approximately 2 μm, was formed, was subjected to a dry etching process using a reactive ion etching apparatus. The reactive ion etching was performed for 15 minutes using CF₄ at 40 sccm and O₂ at 5 sccm under a pressure of 10 mTorr and 100 W of power. The substrate, formed with the photoresist pattern and etched in the reactive ion etching process, was treated using acetone, whereby the photoresist pattern was removed from the substrate.

As a result of analysis of the substrate, etched in the reactive ion etching process after removal of the photoresist pattern, using a scanning electron microscope, it was confirmed that the etched depth was 200 nm.

### EXAMPLE 5

The substrate fabricated in Example 2, on which the dotted photoresist pattern, in which the diameter of the circular structures was approximately 10 m and the distance between the circular structures was approximately 10 μm, was formed, was subjected to a dry etching process using inductively coupled plasma. The inductively coupled plasma process was performed for 10 minutes using CHF₃ at 90 sccm and SF₆ at 10 sccm under a pressure of 8 mTorr and 50 W of power. The substrate, formed with the photoresist pattern and etched in the inductively coupled plasma process, was processed using acetone, whereby the photoresist pattern was removed from the substrate.

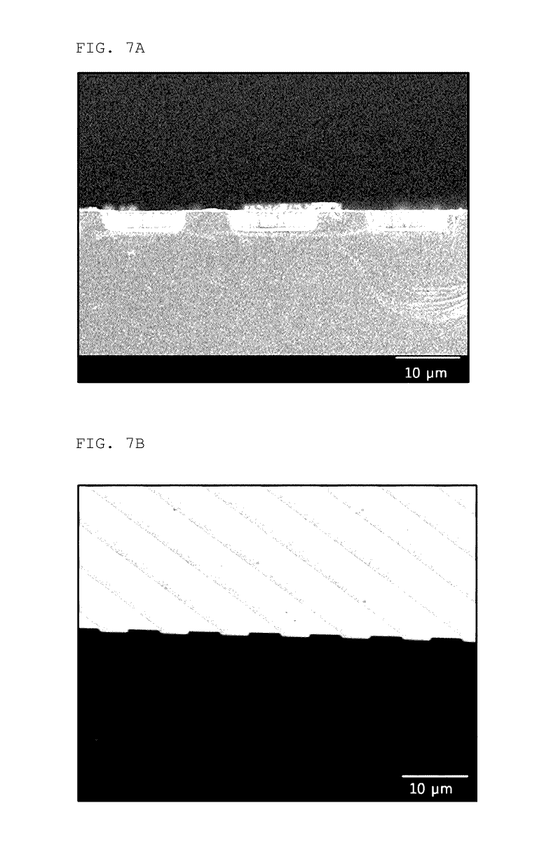

As a result of analysis of the substrate, etched in the inductively coupled plasma process after removal of the photoresist pattern, using a scanning electron microscope, as illustrated in FIG. 7A, it was confirmed that the etched depth was 2 m.

### EXAMPLE 6

A striped photoresist pattern, in which the width of bar-shaped structures was approximately 4.5 m and the distance between the bar-shaped structures was approximately 4.5 μm, was fabricated using the same method as in Example 3.

Subsequently, as a result of performing a dry etching process using a reactive ion etching apparatus via the same method as in Example 4 and removing the photoresist pattern, as illustrated in FIG. 7A, it was confirmed that the etched depth was 200 nm.

### EXAMPLE 7

The etched substrate, fabricated in Example 4, was subjected to a wet etching process using a potassium hydroxide solution. The wet etching process was performed for 10 minutes at a temperature of 60° C. using a potassium hydroxide solution having a molar concentration of 5 M. The silicon substrate, etched in the wet etching process, was washed by distilled water and blown with nitrogen, and was treated with hydrogen fluoride for 10 minutes so as to remove the silicon nitride layer coated over the surface of the substrate, and thereafter was washed with distilled water and acetone and blown with nitrogen. As a result of analysis of the silicon template, from which the silicon nitride layer had been removed, using a scanning electron microscope, it was confirmed that engraved structures, formed by etching, were inverted pyramidal structures, which had a size of approximately 2 m and a distance therebetween of approximately 2 m.

### EXAMPLE 8

The etched substrate, fabricated in Example 5, was subjected to a wet etching process and hydrogen fluoride treatment via the method of Example 7. As a result of analysis of the silicon template, from which the silicon nitride layer had been removed, using a scanning electron microscope, it was confirmed that engraved structures, formed by etching, were inverted pyramidal structures, having a size of approximately 10 m and a distance therebetween of approximately 10 m.

### EXAMPLE 9

It was confirmed that engraved trapezoidal pyramidal structures each having a flat upper surface were formed using the same method as in Example 8 except that the wet etching process was performed for 5 minutes, rather than 10 minutes.

### EXAMPLE 10

The dry-etched substrate of Example 6 was subjected to a wet etching process and hydrogen fluoride treatment using the method of Example 7. As a result of analysis of the silicon template, from which the silicon nitride layer had been removed, using a scanning electron microscope, it was confirmed that inverted prism-shaped structures, having a width of approximately 4-5 m and a distance therebetween of approximately 4-5 m, were formed.

### EXAMPLE 11

A photoresist pattern was fabricated via the method of Example 1 except that the substrate of Example 1, which was coated with silicon nitride, was replaced with a substrate coated with silicon dioxide. Subsequently, a silicon template was fabricated by performing a dry etching process via the method of Example 4, and subsequently, performing a wet etching process via the method of Example 7.

As a result of analysis of the fabricated silicon template with a scanning electron microscope, it was confirmed that engraved inverted pyramidal structures, having a size of approximately 2 μm and a distance therebetween of approximately 2 μm, were formed.

### EXAMPLE 12

The surface of the silicon template of Example 7 was washed using a piranha solution, which was prepared by mixing sulfuric acid and hydrogen peroxide at a ratio of 1:1, and a chemical oxide film was formed on the washed surface of the silicon template. Subsequently, Ag was deposited using a thermal evaporation process. The deposition using the thermal evaporation method was performed at a rate of 1˜2 Å/sec under a pressure of 10⁻⁷ torr. As a result of analysis of the thickness of the deposited Ag using a quartz crystal microbalance (QCM), it was confirmed that the thickness was 180 nm. This is illustrated in FIG. 1B.

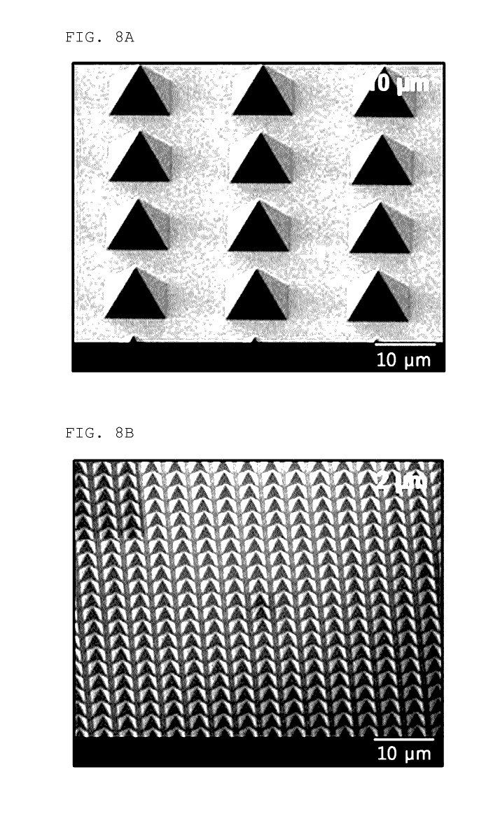

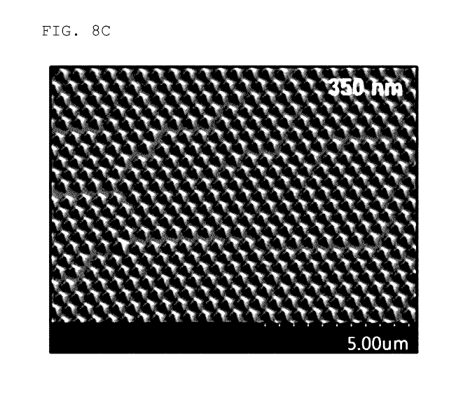

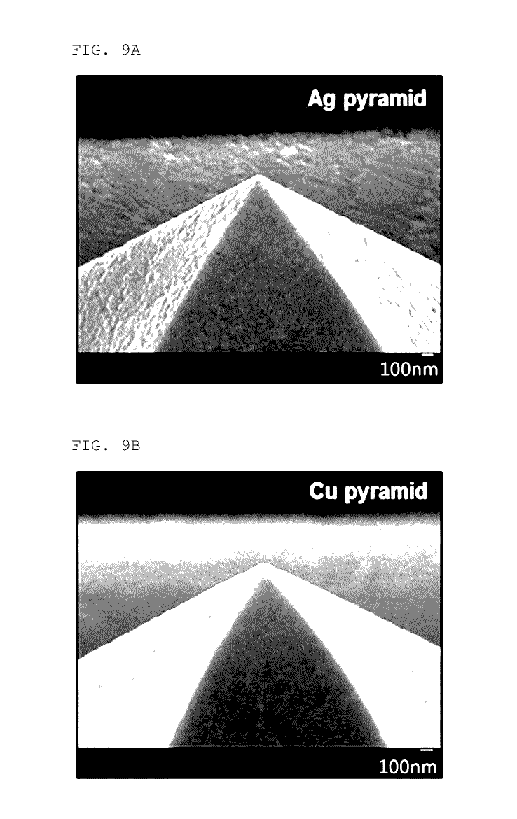

An adhesive in which an epoxy resin and a curing agent were mixed at a ratio of 1:1 was applied to the surface of the silicon template on which the Ag had been deposited, and a thermosetting treatment process was performed for 2 hours at a temperature of 120° C. A lower electrode, which comprised a polymer resin base and a thin metal layer and had a 3D structural pattern, was fabricated by performing a template stripping process on the silicon template, which had undergone the Ag deposition and thermosetting treatment processes, using a razor blade. As a result of analysis of the fabricated lower electrode using a scanning electron microscope, as illustrated in FIG. 8B, it was confirmed that a pyramid pattern, in which the size w of structures and a distance P between one structure and an adjacent structure were approximately 2 was formed.

### EXAMPLE 13

A lower electrode, on which a thin Ag layer had been deposited, was fabricated using the silicon template of Example 8 and the method of Example 12. Based on the analyzed result using a scanning electron microscope, as illustrated in FIG. 8A, it was confirmed that a pyramidal pattern, in which the size w of structures and the distance P between one structure and an adjacent structure were approximately 10 μm, was formed.

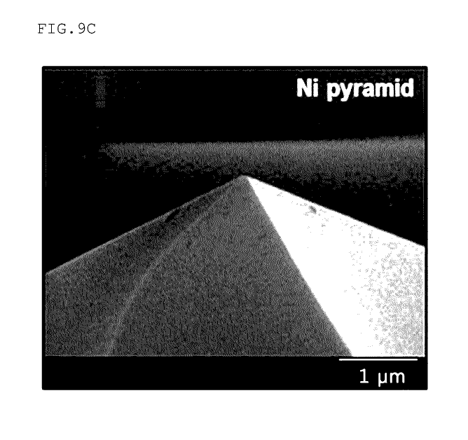

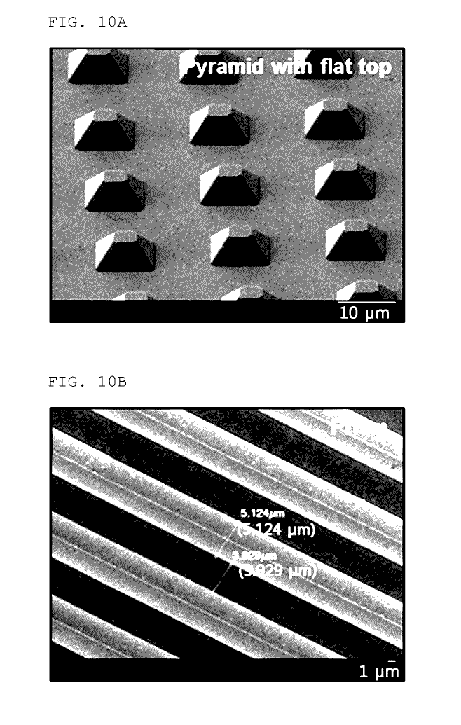

Based on the analyzed result using the scanning electron microscope, the radius of curvature of the protruding structures (pyramids) was approximately 30 nm, as illustrated in FIG. 9A.

### EXAMPLE 14

A lower electrode was fabricated via the same method as that in Example 13 except that Cu was deposited instead of Ag, and it was confirmed that the lower electrode had a pyramidal pattern in which the size w of structures and the distance P between one structure and an adjacent structure were approximately 10 μm. Based on the analyzed result using a scanning electron microscope, the radius of curvature of the protruding structures (pyramids) was approximately 20 nm, as illustrated in FIG. 9B.

### EXAMPLE 15

A lower electrode was fabricated via the same method as Example 13 except that Ni was deposited instead of Ag, and it was confirmed that the lower electrode had a pyramidal pattern in which the size w of structures and the distance between one structure and an adjacent structure were approximately 10 m. Based on the analyzed result using a scanning electron microscope, the radius of curvature of the protruding structures (pyramids) was approximately 50 nm, as illustrated in FIG. 9C.

### EXAMPLE 16

A lower electrode was fabricated via the same method as in Example 13 using an adhesive in which acryl resin and a curing agent were mixed at a ratio of 20:1, instead of the adhesive in which epoxy resin and a curing agent were mixed at a ratio of 1:1. Thereby, the 3D Ag pyramid based lower electrode, having a pyramidal pattern in which the size w of structures and the distance P between one structure and an adjacent structure were approximately 10 μm, was fabricated. Based on the analyzed result using a scanning electron microscope, the radius of curvature of the protruding structures (pyramids) was approximately 30 nm.

### EXAMPLE 17

A lower electrode was fabricated via the same method as in Example 13 using a phenol adhesive, instead of an adhesive in which epoxy resin and a curing agent were mixed at a ratio of 1:1. Thereby, the 3D Ag pyramid based lower electrode, having a pattern in which the size w of structures and the distance P between one structure and an adjacent structure were approximately 10 μm, was fabricated. Based on the analyzed result using a scanning electron microscope, the radius of curvature of the protruding structures (pyramids) was approximately 30 nm.

### EXAMPLE 18

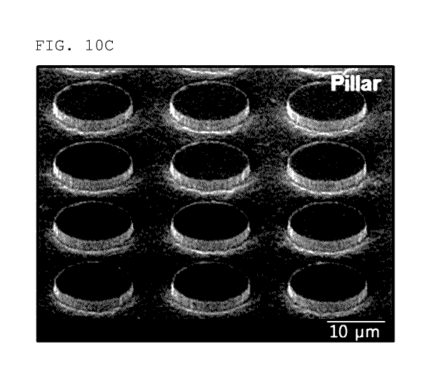

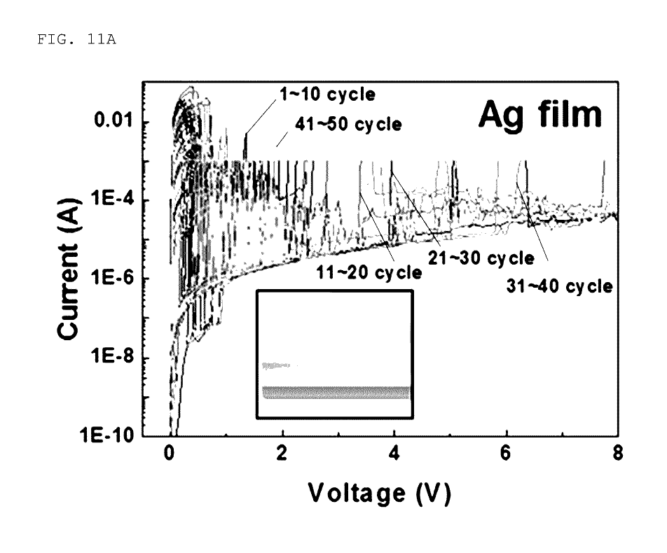

A lower electrode, which had a thin Ag layer, was fabricated using the inverted trapezoidal pyramidal silicon template of Example 9 and the method of Example 12. Based on the analyzed result using a scanning electron microscope, as illustrated in FIG. 10A, the lower electrode based on a trapezoidal pyramid (i.e. a pyramid with the flat top) pattern was fabricated.

### EXAMPLE 19

A lower electrode, which had a thin Ag layer, was fabricated using the inverted prism-shaped silicon template of Example 10 and the method of Example 12. Based on the analyzed result using a scanning electron microscope, as illustrated in FIG. 10B, the lower electrode, based on a prism pattern in which the width w of embossed bar-shaped structures and the distance P between the bar-shaped structures were 4 μm, was fabricated.

### EXAMPLE 20

A lower electrode was fabricated using the substrate fabricated in Example 5 and the method of Example 12.

Thereby, the measured thickness of the deposited Ag was approximately 1 μm, and the lower electrode, having a 3D pillar pattern in which the diameter and thickness of structures were approximately 10 μm and 2 μm respectively, was fabricated.

### EXAMPLE 21

A nonvolatile resistance random access memory was fabricated by sequentially forming an insulator film and an upper electrode on a lower electrode, which was based on a 3D structural pattern having pyramidal structures formed of the thin Ag layer fabricated in Example 12.

Specifically, the insulator film was deposited on the surface of the lower electrode via a sputtering process. The deposition using the sputtering process was performed using Al₂O₃ as the insulator film under a vacuum of 10⁻⁶ torr, a pressure of 5.5 mTorr, and 100 W of power. As a result of analysis of the thickness of the deposited Al₂O₃ using a scanning electron microscope, the measured thickness was 210 nm, and this is illustrated in FIG. 1B.

Subsequently, the upper electrode was formed by depositing Pt on the surface of the Al₂O₃ insulator film, which in turn was deposited on the surface of the lower electrode, using a sputtering process. The deposition using the sputtering process for the formation of the upper electrode was performed using Pt and Ar at 40 sccm under a vacuum of 10⁻⁶ torr, a pressure of 10 mTorr, and 250 W of power. As a result of analysis of the thickness of the upper electrode, the measured thickness was 70 nm.

### EXAMPLE 22

A nonvolatile resistance random access memory device was fabricated via the same method as in Example 21 except that the insulator film was formed of SiO₂ instead of Al₂O₃ and the deposition process was performed using N₂ at 40 sccm under a vacuum of 10⁻⁶ torr, a pressure of 5 mTorr, and 200 W of power. As a result of analysis of the thickness of the upper electrode, the measured thickness was 100 nm.

### EXAMPLE 23

A nonvolatile resistance random access memory device was fabricated via the same method as in Example 21 except that the insulator film was formed of TiO₂ instead of Al₂O₃ and the deposition process was performed using N₂ at 40 sccm under a vacuum of 10⁻⁶ torr, a pressure of 10 mTorr, and 150 W of power. As a result of analysis of the thickness of the upper electrode, the measured thickness was 100 nm.

### EXAMPLE 24

A nonvolatile resistance random access memory device was fabricated via the same method as in Example 21 except that the insulator film was deposited via an atomic layer deposition process instead of the sputtering process. In addition, the insulator film was formed of HfO₂ instead of Al₂O₃ and the deposition process was performed using N₂ at 5 sccm, O₂ at 5 sccm and Ar at 1000 sccm under 300 W of power at a temperature of 340° C. As a result of analysis of the thickness of the upper electrode, the measured thickness was 20 nm.

### EXAMPLE 25

A p-type silicon substrate, which was coated with a 100 nm silicon nitride layer, was placed in a glass tank containing isopropyl alcohol(IPA), and the substrate was washed using an ultrasonic process. The washed substrate was again washed using isopropyl alcohol and blown with nitrogen. The washed substrate was placed in a glass tank containing methanol, and was again washed using an ultrasonic process, and thereafter was washed using methanol and blown with nitrogen. The washed substrate was placed in a glass tank containing acetone, and was again washed using an ultrasonic process. Thereafter, the washing of the substrate was completed using acetone and blown with nitrogen.

After preparing a 5 wt % polystyrene (PS) solution by adding polystyrene to a solution in which water and ethanol were mixed at a ratio of 1:1, a 500 nm PS layer was coated over the substrate using spin coating equipment for 1 minute at a rate of 1500 rpm, whereby a mask having a thickness of approximately 1 m was formed on the substrate.

Subsequently, after performing a dry etching process via the method of Example 4, a 10 nm chrome (Cr) layer was deposited using a thermal evaporation process.

Subsequently, after removing the PS using acetone, a dry etching process was again performed according to the method of Example 4.

Subsequently, after removing a silicon nitride layer from the substrate by performing a wet etching process via the same method as in Example 7, the surface of the substrate was washed using a piranha solution via the method of Example 12. Thereafter, a 180 nm Ag layer was deposited using a thermal evaporation process. Subsequently, an adhesive in which an epoxy resin and a curing agent were mixed at a ratio of 1:1 was applied to the surface of the silicon template on which the Ag had been deposited, and a thermosetting treatment process was performed for 2 hours at a temperature of 120° C. A lower electrode based on a 3D structural pattern was fabricated by performing a template stripping process on the silicon template, which had undergone the Ag deposition and thermosetting treatment processes, using a razor blade.

### EXAMPLE 26

The surface of the silicon template of Example 7 was washed using a piranha solution, prepared by mixing sulfuric acid and hydrogen peroxide at a ratio of 1:1, and a chemical oxide film was formed on the washed surface of the silicon template. Subsequently, Ag was deposited using a thermal evaporation process. The deposition using the thermal evaporation method was performed at a rate of 1˜2 Å/sec and a pressure of 10⁻⁷ torr, thereby forming a 180 nm Ag layer.

Subsequently, as represented in FIG. 12, an electroplating apparatus was prepared. Electroplating was performed at room temperature under conditions whereby H₂SO₄ (1 M) and CuSO₄ (0.25 M) were used as an electrolyte solution, a copper (Cu) foil having a thickness of 25 m was connected to a positive (+) electrode, and the silicon template, on which the Ag had been deposited, was connected to a negative (−) electrode. Thereby, it was confirmed that a thick copper layer was formed on the thin Ag layer.

With the process described above, a lower electrode based on a 3D structural pattern in which pyramidal structures, which had a height and width of 2 m and a distance therebetween of approximately 2 μm, were repeatedly formed, was fabricated.

A nonvolatile resistance random access memory device was fabricated by forming an insulator film (Al₂O₃, 210 nm) and an upper electrode (Pt, 70 nm) using the fabricated lower electrode via the method of Example 21.

### EXPERIMENTAL EXAMPLE 1

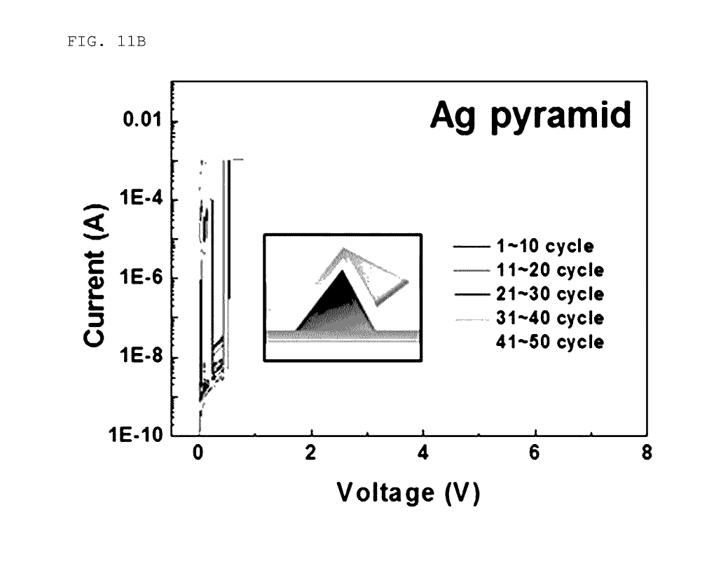

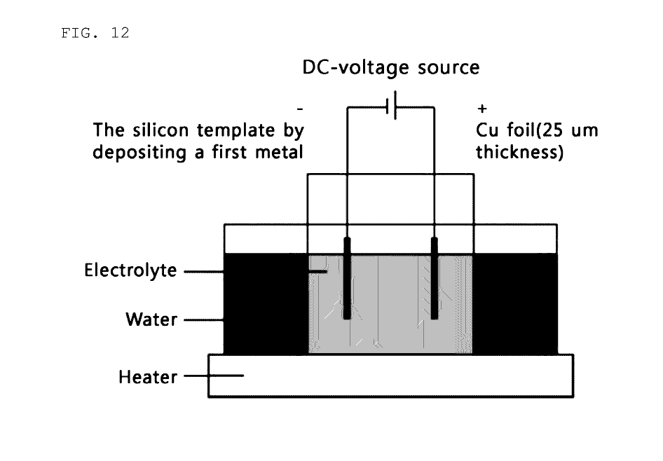

After fabricating a memory device, which was provided as a comparative example, by depositing an Al₂O₃ insulator film having a thickness of 210 nm over the Ag lower electrode having a thickness of 180 nm, and depositing an upper electrode having a thickness of 70 nm, the performance of the memory device was measured via the same method as the above description. This is illustrated in FIG. 11A.

The performance of the nonvolatile resistance random access memory device, fabricated in Example 21 of the present invention, was measured using memory measurement equipment (namely an Agilent 4155c semiconductor characterization system). A copper tape and silver paste were connected to the surface of the lower electrode based on the 3D Ag pyramidal pattern, and a copper line was connected to the upper electrode. This is illustrated in FIG. 2. Subsequently, the performance of the memory device was measured, and this is illustrated in FIG. 11B.

It was confirmed from the measured results that, although the comparative device showed memory characteristics including a set operating voltage within the range from 1.0 V to 8.0 V, a reset operating voltage within the range from 0.1 V to 1.0 V and a resistance ratio of 10² when repeatedly measured 50 times, the device in accordance with the present invention showed memory characteristic including a set operating voltage within the range from 0.2 V to 0.4 V, a reset operating voltage within the range from 0.01 V to 0.05 V, and a resistance ratio of 10⁴ when repeatedly measured 50 times.

### EXPERIMENTAL EXAMPLE 2

In a nonvolatile resistance random access memory device in accordance with the present invention, in order to confirm variation in the performance of the memory device depending on the shape and size of 3D structures, the radius of the tip, and variation in the thicknesses of the first metal and the insulator film, memory devices having various conditions were fabricated, and then the performance thereof was measured. This is represented in the following Table 1. The insulator film was formed of Al₂O₃.

TABLE 1

| | | Radius of | | | Thickness | Set | Reset | |
|---|---|---|---|---|---|---|---|---|
| Shape of | Size | Curvature | First | Base | of Insulator | Range | Range | resistance |
| Structure | (μm) | (nm) | Metal | Material | Film (nm) | (V) | (V) | ratio |
| Pyramid | 2 | 30 | Ag | Polymer | 210 | 0.3-0.4 | 1.01-0.05 | 10⁶ |
| | 0.35 | 30 | Ag | Polymer | 210 | 0.3-0.7 | 0.03-0.1 | 10⁶ |
| | 10 | 30 | Ag | Polymer | 210 | 0.5-0.7 | 0.1-0.3 | 10⁵ |
| | 2 | 20 | Ag | Polymer | 210 | 0.7-1.0 | 0.05-0.2 | 10⁵ |
| | 2 | 70 | Ag | Polymer | 210 | 0.7-1.0 | 0.1-0.3 | 10⁴ |
| | 2 | 20 | Cu | Polymer | 210 | 0.4-0.7 | 0.1-0.2 | 10⁶ |
| | 2 | 50 | Ni | Polymer | 210 | 0.5-0.7 | 0.2-0.3 | 10⁶ |
| | 2 | 20 | Ag | Polymer | 450 | 0.7-1.0 | 0.1-0.2 | 10⁶ |
| | 2 | 20 | Ag | Polymer | 730 | 1 | 0.2-0.3 | 10⁶ |
| | 2 | 10 | Ag | Polymer | 210 | 0.8-1.0 | 0.05-0.2 | 10⁵ |
| | 2 | 30 | Ag | Metal (Cu) | 210 | 0.3-0.4 | 0.01-0.06 | 10⁶ |
| Prism | 4.5 | — | Ag | Polymer | 210 | 0.7-0.9 | 0.1-0.3 | 10⁵ |
| Pillar | 10 | — | Ag | Polymer | 210 | 0.8-1.0 | 0.2-0.3 | 10⁴ |
| Pyramid | 10 | — | Ag | Polymer | 210 | 0.7-1.0 | 0.1-0.3 | 10⁵ |
| with flat top | | | | | | | | |

As represented in Table 1, it was confirmed that the nonvolatile resistance random access memory device in accordance with the present invention is capable of being driven at a low and reliable operating voltage and of exhibiting the uniform distribution of current.

As is apparent from the above description, the present invention provides a method of fabricating a nonvolatile resistance random access memory device, the method including fabricating a template, and fabricating a lower electrode based on a 3D structural pattern having a thin metal layer using the template. Owing to the lower electrode including the 3D structural pattern in which a plurality of protruding structures is repeatedly arranged at a constant interval, the nonvolatile resistance random access memory device in accordance with the present invention includes uniform conductive filaments formed inside an insulator film, thereby being drivable even at a low operating voltage of 1V or less and exhibiting rapid switching and a high resistance ratio of 10⁴ or more. Thereby, the nonvolatile resistance random access memory device may be usefully used as a next-generation memory and may achieve excellent switching reproducibility, and consequently improved reliability. In addition, the formation of the conductive filaments may be adjusted by adjusting the size of the protruding structures and the distance between the protruding structures.

What is claimed is:

1. A method of fabricating a nonvolatile resistance random access memory device, the method comprising:
forming a mask on a substrate;
forming a mask pattern on the mask;
etching the substrate by performing a dry etching process on the substrate, on which the mask pattern has been formed;
fabricating a silicon template by performing a wet etching process on the dry-etched substrate;
fabricating a lower electrode including a 3D structural pattern in which protruding structures are repeatedly arranged at a constant interval by performing operations of forming a thin metal layer on the silicon template by depositing a first metal, and of forming a base by performing a template stripping process or an electroplating process, which includes a polymer curing process, on the silicon template on which the thin metal layer has been formed;
fabricating an insulator film by depositing a metal oxide on a surface of the lower electrode; and
fabricating an upper electrode by depositing a second metal over the insulator film.

2. The method according to claim 1, wherein the mask pattern is a dotted pattern in which circular structures are repeatedly formed at a constant interval, or a striped pattern in which bar-shaped structures are repeatedly formed at a constant interval.

3. The method according to claim 1, wherein the dry etching process is selected from among a reactive ion etching process and an inductively coupled plasma etching process.

4. The method according to claim 1, wherein the first metal and the second metal are the same as or different from each other, and each of the first metal and the second metal is independently formed such that one selected from among platinum, nickel, tungsten, gold, silver, copper, titanium, aluminum, cobalt, tin, palladium, zinc, manganese, and iron is deposited to a thickness within a range from 10 nm to 1000 nm.

5. The method according to claim 1, wherein the base is formed of a polymer resin or metal,
wherein the polymer resin is any one selected from among acryl resin, urethane resin, epoxy resin, polyester resin, phenol resin, polyvinyl chloride, amino, and polyacetal, and
wherein the metal is any one selected from among silver (Ag), copper (Cu), nickel (Ni), chrome (Cr), platinum (Pt), gold (Au), lead (Pb), ruthenium (Ru), and palladium (Pd).

6. The method according to claim 1, wherein the protruding structures of the lower electrode have a shape selected from among a pyramid, a trapezoidal pyramid (pyramid with a flat top), a pillar, and a prism.

7. The method according to claim 1, wherein the protruding structures of the lower electrode have a height within a range from 100 nm to 100 m, and a width (or diameter) within a range from 100 nm to 100 m, and an interval (or distance) between one structure and an adjacent structure is within a range from 100 nm to 100 m.

8. The method according to claim 1, wherein the protruding structures of the lower electrode have a shape of a pyramid, and
wherein a tip of the pyramid includes a curved surface and has a radius of curvature within a range from 10 nm to 100 nm.

9. The method according to claim 1, wherein the insulator film is formed by depositing one kind of metal oxide selected from among NiO, SiO₂, TiO₂, ZnO, HfO₂, Nb₂O₅, MgO, Al₂O₃, Ta₂O₅, CuO, ZrO₂, and Fe₂O₃, on a surface of the lower electrode.

10. The method according to claim 1, wherein the insulator film has a thickness within a range from 10 nm to 1000 nm.

11. The method according to claim 1, wherein the upper electrode has a thickness within a range from 10 nm to 1000 nm.

12. The method according to claim 1, wherein the nonvolatile resistance random access memory device has a set operating voltage within a range from 0.3 V to 1.0 V, a reset operating voltage within a range from 0.01 V to 0.3 V, and a resistance ratio within a range from 10⁴ to 10⁶.

13. The nonvolatile resistance random access memory device manufactured by the process of claim 1.
